(19) United States
(12) Patent Application Publication
(10) Pub. No.: US 2023/0135889 A1
(43) Pub. Date: May 4, 2023

(54) INTEGRATED CIRCUIT DEVICE WITH IMPROVED OXIDE EDGING

(71) Applicant: Texas Instruments Incorporated, Dallas, TX (US)

(72) Inventors: Abbas Ali, Plano, TX (US); Christopher Scott Whitesell, Garland, TX (US); John Christopher Shriner, Lucas, TX (US); Henry Litzmann Edwards, Garland, TX (US)

(21) Appl. No.: 17/514,786

(22) Filed: Oct. 29, 2021

(51) Int. Cl. H01L 21/762; H01L 27/06; H01L 29/78; H01L 29/66

(52) U.S. Cl. CPC H01L 21/76221; H01L 27/0629; H01L 29/7817; H01L 29/66689

(57) ABSTRACT

A method of forming an integrated circuit forms a first oxygen diffusion barrier layer in a fixed position relative to a semiconductor substrate and forms an aperture through the first oxygen diffusion barrier layer to expose a portion of the semiconductor substrate. The method also forms a first LOCOS region in an area of the aperture and a second oxygen diffusion barrier layer along the first LOCOS region and along at least a sidewall portion of the first oxygen diffusion barrier layer in the area of the aperture. The method also deposits a polysilicon layer, at a temperature of 570° C. or less, over the second oxygen diffusion barrier layer, etches the polysilicon layer and the second oxygen diffusion barrier layer to form a spacer in the area of the aperture, and forms a second LOCOS region in the area of the aperture and aligned to the spacer.

### CROSS-REFERENCE TO RELATED APPLICATION

Not applicable.

### BACKGROUND

The example embodiments relate to semiconductor integrated circuit (IC) fabrication, and more particularly to an IC that includes one or more oxide regions, such as LOCal Oxidation of Silicon (LOCOS) regions.

LOCOS is a semiconductor fabrication process and its resultant silicon dioxide structure, typically formed so that a least a portion of the silicon dioxide structure extends below the surface of a silicon semiconductor substrate. In a conventional process, some or all of the semiconductor substrate is covered with an oxygen diffusion barrier material, such as silicon nitride. Thereafter, one or more openings are made through the oxygen diffusion barrier material, thereby exposing a respective surface of the semiconductor substrate through the opening. Lastly, the exposed opening is exposed to oxygen (oxidation is performed), and the oxygen reacts with the silicon and transforms it into a silicon dioxide region, which typically tapers in shape toward the outer perimeter of the region, that is, toward the outer edge(s) of the opening that was formed through the diffusion barrier material.

LOCOS regions may be formed in connection with various IC structures. For example, LOCOS may be used to isolate one metal oxide semiconductor (MOS) transistor from another. As another example, LOCOS may be used to create a relatively thicker oxide adjacent (or abutting with) a thinner oxide in a raised integration process, that is, where a later-formed structure, such as a gate conductor, is positioned/formed to overlie a portion of the thicker portion and a portion of the thinner portion. These structures may exist, for example, in a laterally-diffused MOS (LDMOS) field effect transistor (FET) or a drain-extended MOS (DEMOS) FET. Additional examples of LOCOS implementation, for example in connection with transistors, are illustrated and described in co-owned U.S. Pat. No. 10,529,812, issued Jan. 7, 2020, which is hereby fully incorporated herein by reference. Additional examples of LOCOS implementation, for example in connection with the dielectric adjacent a capacitor plate, or between capacitor plates, are illustrated and described in co-owned U.S. Pat. No. 10,707,296, issued Jul. 7, 2020, which is hereby fully incorporated herein by reference.

While the preceding has implementation in various prior art devices, this document provides example embodiments that may improve on certain of the above concepts, as detailed below.

### SUMMARY

In an example embodiment, a method of forming an integrated circuit is described. The method forms a first oxygen diffusion barrier layer in a fixed position relative to a semiconductor substrate and forms an aperture through the first oxygen diffusion barrier layer and to expose a portion of the semiconductor substrate in an area of the aperture. The method also forms a first LOCOS region by oxidizing the portion of the semiconductor substrate in an area of the aperture and forms a second oxygen diffusion barrier layer along the first LOCOS region and along at least a sidewall portion of the first oxygen diffusion barrier layer in the area of the aperture. The method also deposits a polysilicon layer, at a temperature of 570° C. or less, over the second oxygen diffusion barrier layer and etches the polysilicon layer and the second oxygen diffusion barrier layer to form a spacer in the area of the aperture. Lastly, the method forms a second LOCOS region in the area of the aperture and aligned to the spacer.

Other aspects are also described and claimed.

### BRIEF DESCRIPTION OF THE DRAWINGS

FIG. 1A through FIG. 10A are partial plan views representing successive fabrication stages and resultant structures of a semiconductor structure.

FIG. 1B through FIG. 10B are cross-section views, corresponding respectively to FIG. 1A through FIG. 10A.

FIG. 11 is a cross-section view of the FIGS. 10A and 10B structure, as implemented in an LDMOS FET.

FIG. 12 is a flow diagram of an example embodiment method for manufacturing a semiconductor structure.

### DETAILED DESCRIPTION

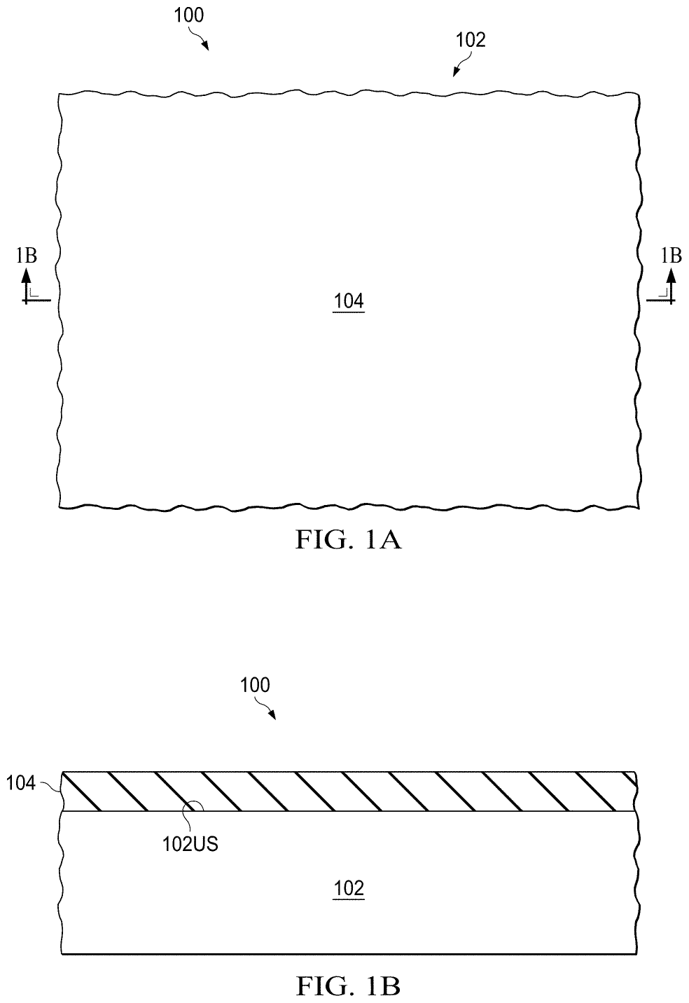

FIG. 1A through FIG. 10A are partial plan views, and FIG. 1B through FIG. 10B are cross-section views corresponding respectively to FIGS. 1A through 10A, representing successive fabrication stages and resultant structures of a semiconductor structure 100. Ultimately, the semiconductor structure 100 will include a relatively thick LOCOS structure or structures, each for example having a thickness of 0.2 μm or more and with improved line edge roughness (LER) along its lateral edges and in an IC die. As one example, the IC die may provide a transistor operating at a voltage greater than associated with traditional planar transistors, for example at 13 volts or more. Such a transistor may be implemented, as examples as a DEMOS FET or an LDMOS FET. Further the IC die may include numerous other devices that function in relation to the transistor. Such devices may be isolated from the structures shown in FIGS. 1A and 1B (and other later figures), for example via field oxides, formed for example using either a shallow trench isolation (STI) or LOCOS process.

Starting with FIGS. 1A and 1B, the semiconductor structure 100 includes a semiconductor substrate 102, for example as part of a silicon wafer. Further, such a wafer typically includes multiple locations, each corresponding to a same or different IC on the wafer, so the illustrations of FIGS. 1A and 1B (and later figures) can be repeated in each wafer IC location. The wafer typically provides either a p-type or n-type semiconductor, and the substrate 102 can represent a portion of the bulk wafer or a region (e.g., a well or buried layer) formed in connection with the wafer. A pad oxide (not shown) may be formed across a wafer upper surface 102US, for example to reduce potential inter-layer strain due to differences in temperature reaction. A first oxygen diffusion barrier layer 104, for example of silicon nitride, is formed along (or fixed in relation to) the upper surface 102US. The first oxygen diffusion barrier layer 104 may be formed using a low pressure chemical vapor deposition (LPCVD) and at a thickness of 400 to 2,000 Å.

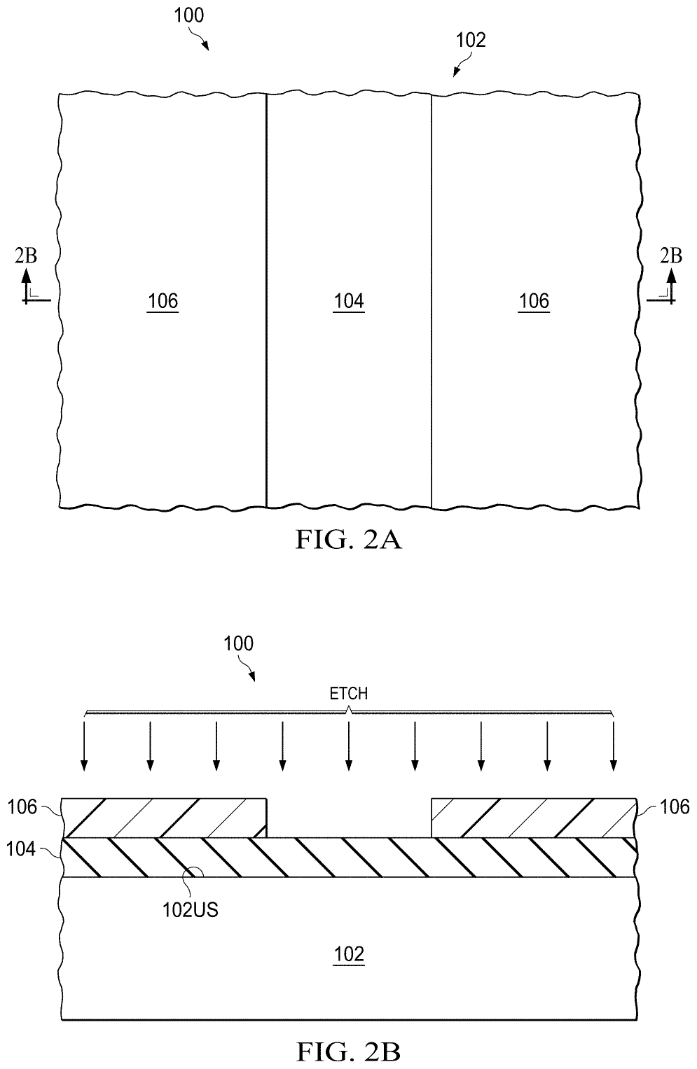

In FIGS. 2A and 2B, an etch mask 106 is formed over a selective portion(s) of the first oxygen diffusion barrier layer 104, for example using a photolithography process. The etch mask 106 leaves exposed areas of the first oxygen diffusion barrier layer 104 in areas where the etch mask 106 is not located. Once the etch mask 106 is so formed and positioned, an etch (e.g., wet etch, plasma) is performed.

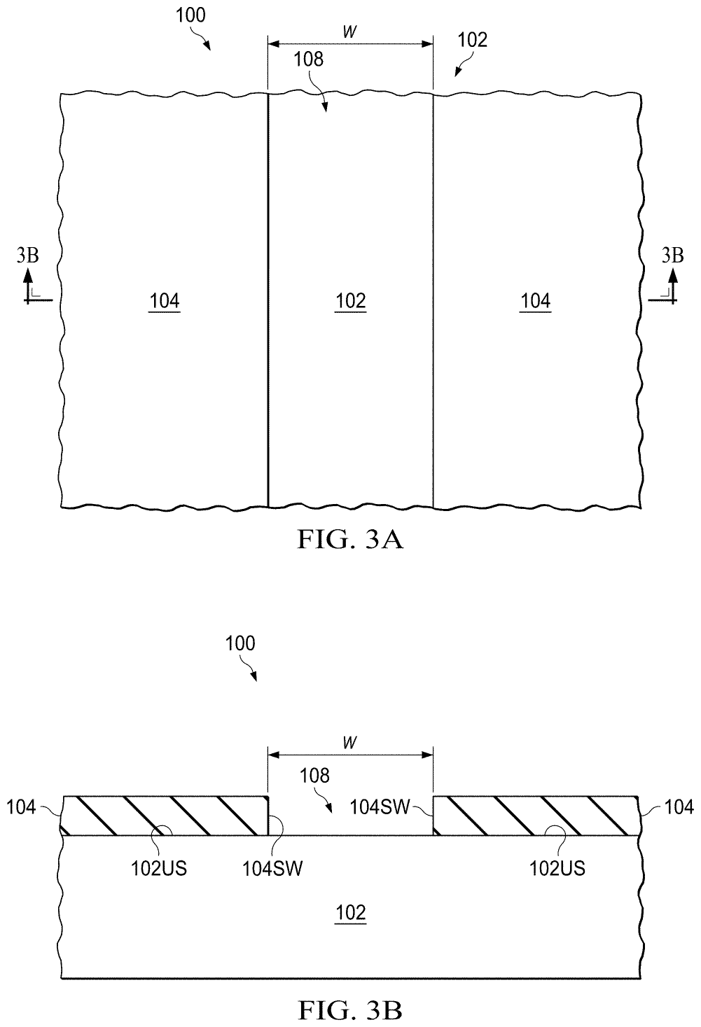

FIGS. 3A and 3B illustrate the result following the FIGS. 2A and 2B etch. The etch removes the first oxygen diffusion barrier layer 104, down to the upper surface 102US, in areas not masked by the mask 106. The masked portions of the first oxygen diffusion barrier layer 104 remain after the etch, thereby forming sidewalls 104SW and an aperture 108 between the sidewalls 104SW. The aperture 108 may have a width W of 0.1 μm≤W≤5 μm. Accordingly, the aperture 108 exposes a portion of the upper surface 102US which, as further shown below, is an area in which an improved LOCOS region, for example a multi-layer LOCOS region, will be formed.

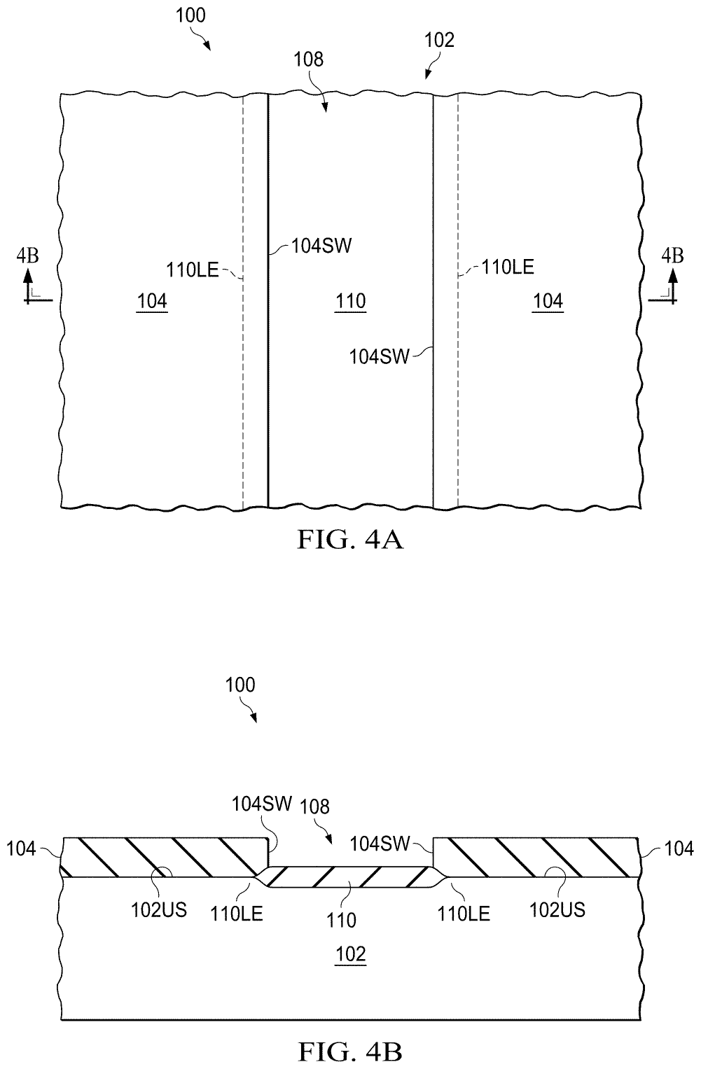

In FIGS. 4A and 4B, a first LOCOS region is formed in any exposed area of silicon, which in the example embodiment forms a first LOCOS region 110 within the aperture 108. The LOCOS process may include, for example, ramped temperatures and varied oxygen concentrations. The LOCOS process oxidizes a portion of the exposed silicon, thereby causing the first LOCOS region 110 to have a thinner vertical cross-section profile at its lateral edges 110LE, with a thicker vertical cross-section (e.g., 200 to 1,000 Å) at the center area between the lateral edges 110LE (and where terms of dimension, such as lateral and vertical, are for relative reference, but not requiring a mandated orientation for a resultant device or application). Further, as the LOCOS oxidation consumes a small portion of silicon beneath the bottom corners of the sidewalls 104SW, the lateral edges 110LE may extend laterally outward relative to the sidewalls 104SW.

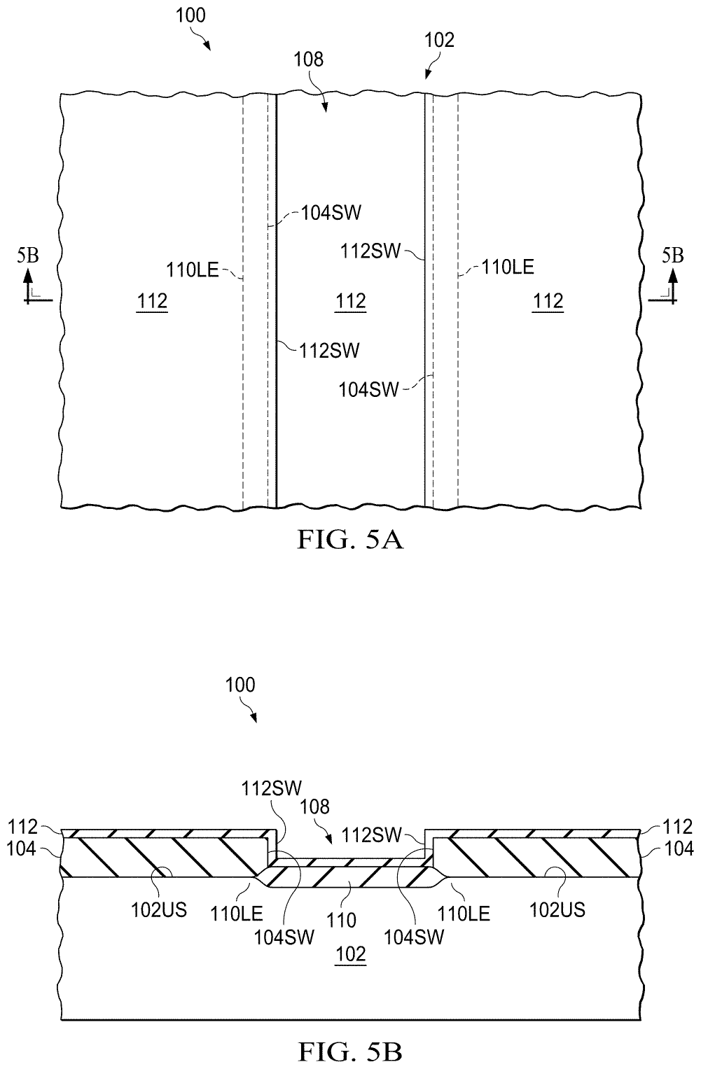

In FIGS. 5A and 5B, a second oxygen diffusion barrier layer 112 is formed over the semiconductor structure 100, which therefore also includes the area between the sidewalls 104SW. Accordingly, the second oxygen diffusion barrier layer 112 also includes sidewalls 112SW, within the aperture 108 and generally parallel to the sidewalls 104SW. In an example embodiment, the second oxygen diffusion barrier layer 112, like the first oxygen diffusion barrier layer 104, is silicon nitride, but having a lesser thickness, for example from 100 to 500 Å.

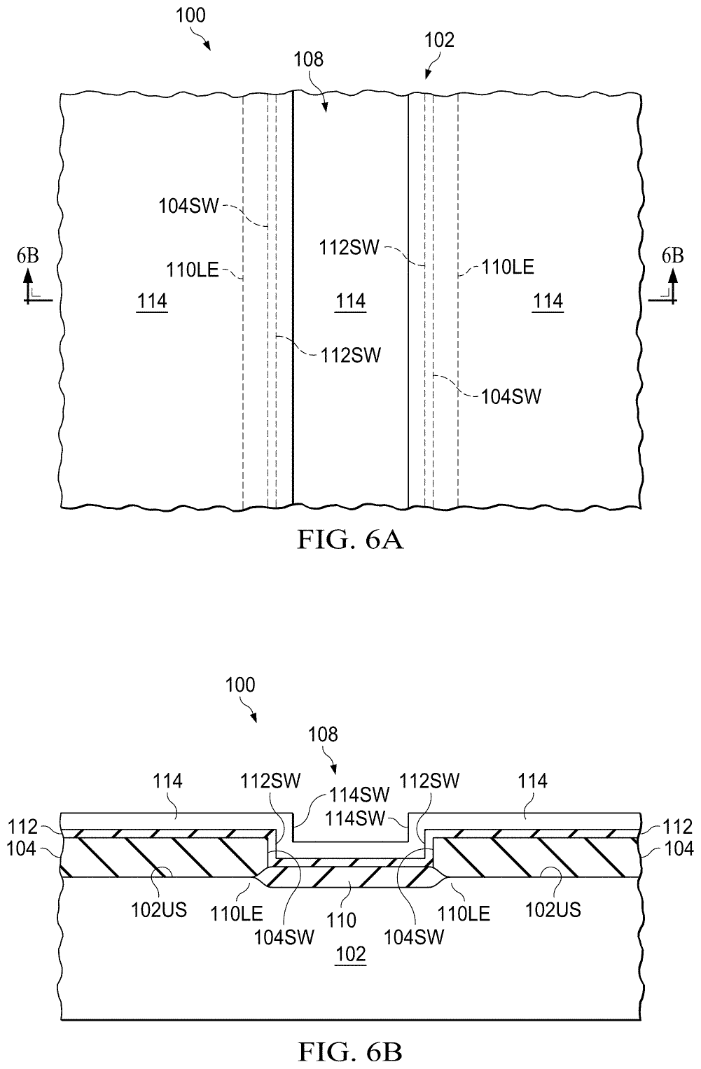

In FIGS. 6A and 6B, a polysilicon sacrificial layer 114 is formed over the semiconductor structure 100, which therefore also includes the area between the sidewalls 104SW. Accordingly, the polysilicon sacrificial layer 114 also includes sidewalls 114SW, generally within the aperture 108 and parallel to the sidewalls 104SW. In an example embodiment, the polysilicon sacrificial layer 114 is deposited at a temperature of 570° C. or less, in order to form amorphous polysilicon. This can be in contrast, for example, to typical transistor gate formation processes, known to deposit polysilicon at higher temperature, resulting in the formation of a polycrystalline structure. In the example embodiment, the lower temperature formation and/or use of amorphous polysilicon forms a solid structure that when subsequently etched provides a more reliable LER, potentially due to the smaller grain size of amorphous polysilicon relative to a polycrystalline alternative, for example in that the lower grain size is more accurately cut in a subsequent etch.

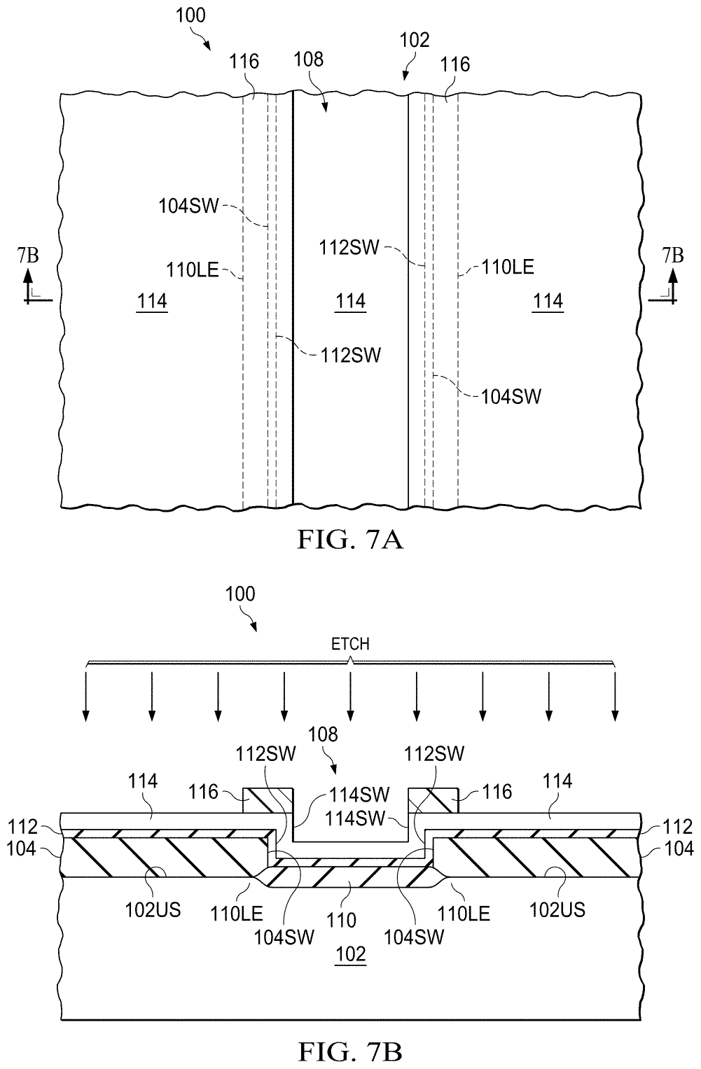

In FIGS. 7A and 7B, an etch mask 116 is formed over a selective portion(s) of the polysilicon sacrificial layer 114, for example using a photolithography process. As further appreciated below, the etch mask 116 is positioned in locations to later cause the formation of sidewall spacers within the aperture 108. Elsewhere are exposed areas of the polysilicon sacrificial layer 114 where the etch mask 116 is not located. Once the etch mask 116 is so formed and positioned, an etch (e.g., plasma, wet) is performed.

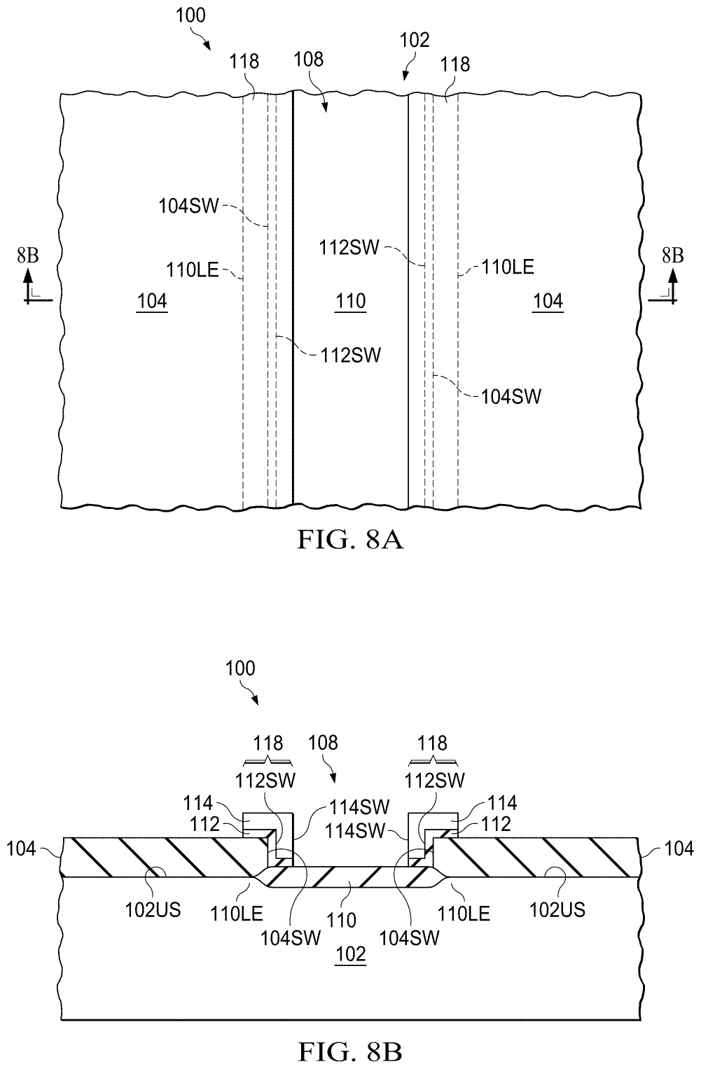

FIGS. 8A and 8B illustrate the result following the FIGS. 7A and 7B etch. Specifically, the etch removes the polysilicon sacrificial layer 114 in areas not masked by the mask 116, and the etch further removes the vertically aligned portions of the second oxygen diffusion barrier layer 112 beneath the polysilicon sacrificial layer 114. Accordingly, the etch stops at the first oxygen diffusion barrier layer 104 outside of the aperture 108, and at the first LOCOS region 110 within the aperture 108. As a result, a combined spacer 118 is formed along the sidewalls 104SW and includes a portion of the polysilicon sacrificial layer 114 and a portion of the second oxygen diffusion barrier layer 112. Further, in accordance with the example embodiment of the combined spacer 118 including amorphous polysilicon, when the amorphous polysilicon is etched, it results in a relatively smooth (not jagged, discontinuous, or rough) material removal along the edges of each combined spacer 118 which, as shown below, provides an improved structure that self-aligns to the smooth edging.

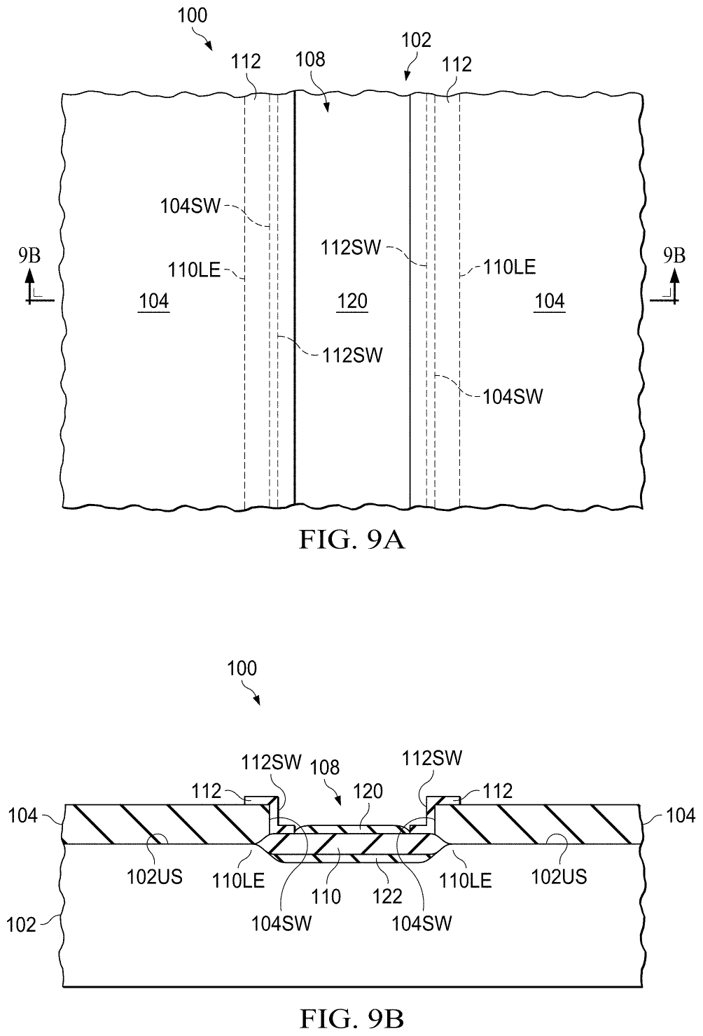

In FIGS. 9A and 9B, the FIGS. 8A/8B polysilicon sacrificial layer 114 portion of each of the combined spacers 118 is stripped (removed), leaving in place the respective portion of the second oxygen diffusion barrier layer 112 from each of the combined spacers 118. This polysilicon removal may be achieved, for example, with a hydrofluoric and nitric acid wet strip. Thereafter, a second LOCOS region is formed in any exposed area of oxide, which in the example embodiment forms a second LOCOS region within the aperture 108 and having two portions, namely, a first LOCOS portion 120 above the first LOCOS region 110 and a second LOCOS portion 122 below the first LOCOS region 110. The second LOCOS formation also may include, for example, ramped temperatures and varied oxygen concentrations. Accordingly, the vertical thickness of the first LOCOS region 110 is effectively enlarged by the combined vertical thickness of the first and second LOCOS portions 120 and 122, for example with the resultant total thickness from 500 to 1,500 Å. Thus, a thicker total LOCOS is achieved in the area of aperture 108, for example in contrast to where other oxides, including other LOCOS regions, may be formed on or in the semiconductor substrate 102, but that are blocked from oxidation during the formation of the second LOCOS region. Further in connection with FIGS. 9A and 9B, the formation of the second LOCOS region self-aligns, within the aperture 108, to the remaining portions of the second oxygen diffusion barrier layer 112 from the combined spacers 118 (see FIGS. 8A and 8B). Thus, the smoothness and linearity of the edges of the second oxygen diffusion barrier layer 112, within the area of the aperture 108, likewise affect the smoothness and linearity of the outer edges of both the first LOCOS portion 120 and the second LOCOS portion 122. Accordingly, the critical dimension (CD) to any aligned structure that is defined in connection with the first LOCOS portion 120 (or the second LOCOS portion 122) is improved in accuracy and consistency, as aligning to the improved smoothness of the spacer 118. Such aligned structure can include other portions of a transistor, a multi-finger transistor, or multiple transistors sharing the same technology and implemented in the same steps, in connection with the substrate 102 and as part of the semiconductor structure 100.

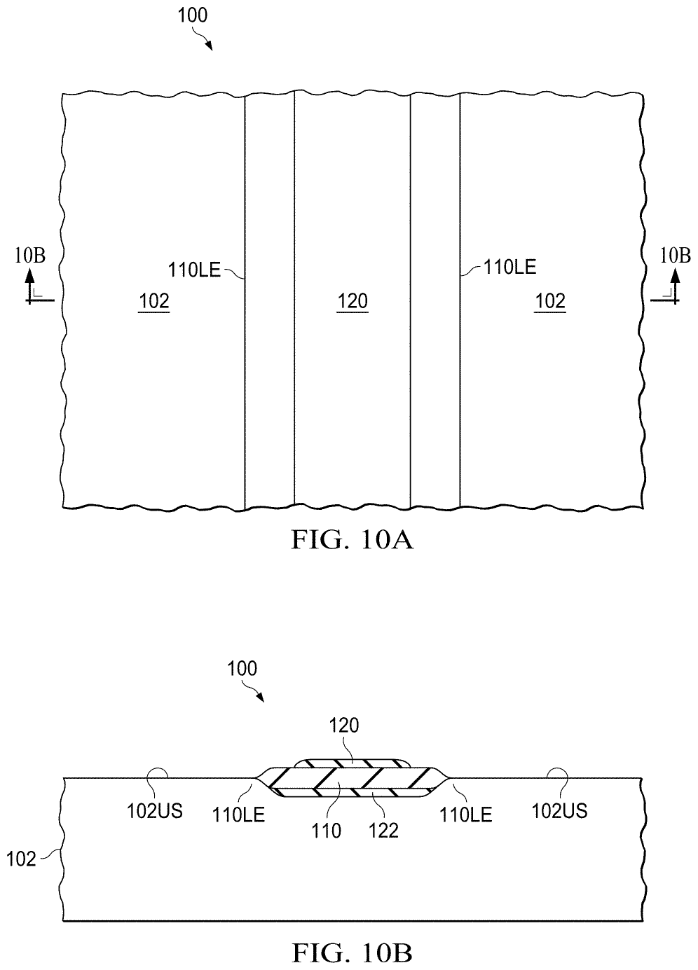

In FIGS. 10A and 10B, all surface exposed silicon nitride is stripped (removed), thereby removing both the second oxygen diffusion barrier layer 112 and the first oxygen diffusion barrier layer 104. This silicon nitride removal may be achieved, for example, with a hot phosphoric acid wet strip. The resultant structure presents the above-described relatively thick LOCOS, which includes the first LOCOS region 110 and the first and second LOCOS portions 120 and 122 of the second LOCOS region. Other structures may be formed adjacent and/or abutting to this relatively thick LOCOS, for example with a transistor including a high voltage transistor, or other devices (e.g., diodes) in which the relatively thick LOCOS is a component or provides isolation or self-alignment. Further, portions of such structures may be formed before, concurrently with, or after the formation of the relatively thick LOCOS. Lastly, such structures, as well as CD considerations among the structures and/or their components, can benefit from the improved thick oxide edge LER achieved by the example embodiment.

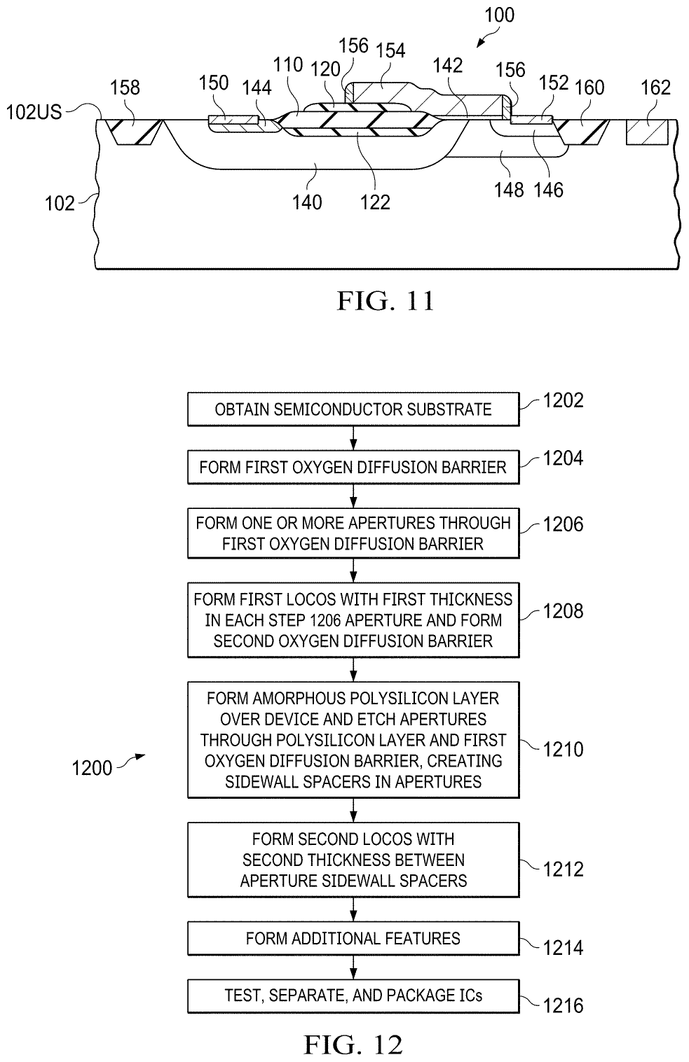

FIG. 11 is a cross-section of the FIGS. 10A and 10B structure as implemented in an example embodiment structure, namely, a LDMOS FET. Various additional portions of the LDMOS FET are shown and can be implemented in steps before, during, or after those described above, and those steps may be implemented using numerous alternative processes and materials as may be known or ascertainable by person of skill in the art. In the substrate 102 and beneath the relatively thick LOCOS that includes the first LOCOS region 110 and the first and second LOCOS portions 120 and 122, there is located a drift region 140, having a conductivity type based on that of the LDMOS FET, where for the current example assume an NPN FET, in which case the drift region 140 is n-type. A portion of the drift region 140 extends below a thin gate oxide 142, formed to abut a portion of the relatively thick LOCOS and also at least in part along the upper surface 102US. A drain 144 is formed within, and having the same conductivity type as, the drift region 140, although with a higher average dopant concentration (e.g., n+ type). A source 146, of a same conductivity type and same or similar dopant concentration (e.g., n+ type) as the drain 144, is formed below the upper surface 102US, and so that a portion of the source 146 is beneath the thin gate oxide 142 and another portion of the source 146 extends laterally away from the thin gate oxide 142. A body 148, of an opposite conductivity type (e.g., p-type) as the source 146 (and the drain 144) is between the source 144 and the drift region 140. Respective silicide regions 150 and 152 are formed over the drain 144 and the source 146. A gate conductor 154, and dielectric sidewalls 156 to the gate conductor 154, are formed over the thin gate oxide 142 and a portion of the relatively thick LOCOS, so that the gate conductor 154 abuts a portion of the first LOCOS region 110 and a portion of the first LOCOS portion 120. Isolation regions (e.g., STI) 158 and 160 are formed within the substrate 102 and outward relative to the drain 144 and the source 148, respectively. Laterally beyond one or both of the isolation regions 158, functional circuitry 162 is formed on or within the substrate 102, where the functional circuitry 162 may include circuit elements (e.g., other transistors, and generally diodes, resistors, capacitors, etc.) that may be configured together with the illustrated LDMOS FET to implement at least one circuit function such as an analog and/or digital function, including as an example an amplifier, power converter or power FET, radio frequency (RF), memory function, or a more complex device including a processor.

FIG. 12 is a flow diagram of an example embodiment method 1200 for manufacturing a semiconductor structure 100, for example as shown in FIG. 11. The flow diagram 1200 begins in a step 1202, in which the FIG. 1A/1B semiconductor substrate 102 is obtained. The semiconductor substrate 102, at this stage, may be a bare wafer or may have one or more semiconductor features already formed on it. The semiconductor substrate 102 also includes one or more areas in which it is desirable to form a relatively thick LOCOS region, and it also may include other areas in which is it desirable to form a relatively thinner LOCOS region.

Next, in a step 1204, a first oxygen diffusion barrier layer 104 is formed over the semiconductor substrate 102. The first oxygen diffusion barrier layer 104 may be formed directly over the semiconductor substrate 102 or with one or more intervening layers, such as a pad oxide, between an upper surface 102US of the semiconductor substrate 102 and the first oxygen diffusion barrier layer 104.

Next, in a step 1206, one or more apertures are formed through the first oxygen diffusion barrier layer 104, by forming mask regions with an opening in each area where the apertures are to be formed, and etching the structure in unmasked areas. Each resultant aperture has a corresponding width, where the widths can be the same among all apertures, or may vary.

Next, in a step 1208, a first LOCOS having a corresponding first thickness may be formed in each step 1206 aperture. After the first (or each) first LOCOS is formed, a second oxygen diffusion barrier layer 112 is formed along the device and, accordingly, over each first LOCOS.

Next, in a step 1210, a polysilicon layer 114 is formed over the entire device, then patterned and etched in unmasked areas down through the second oxygen diffusion barrier layer 112. The polysilicon layer 114 is desirably deposited at a temperature of 570° C. or less, thereby forming amorphous polysilicon. In areas where the polysilicon layer 114 is within a relatively small width aperture, the polysilicon may pinch off the area, that is, it may prevent the etch from reaching all the way through the polysilicon and down to and/or through the second oxygen diffusion barrier layer 112, while in areas of wider apertures (or elsewhere along relatively large planar areas), the etched is through the second oxygen diffusion barrier layer 112, for example creating combined sidewall spacers within the relatively wider apertures, with such spacers including a polysilicon portion above and conforming to a respective lower portion of the second oxygen diffusion barrier layer 112.

Next, in a step 1212, a second LOCOS is formed between the combined sidewall spacers, so that in combination with the first LOCOS a relatively thicker total LOCOS is realized in such areas, for example as compared to narrower apertures in which the pinched off polysilicon prevents an etch down to the substrate and thereby also prevents a second LOCOS that otherwise would thicken the first LOCOS previously formed in such areas. Thereafter, any remnants of the combined spacers and/or polysilicon layer 114, the second oxygen diffusion barrier 112, and the first oxygen diffusion barrier 104 are removed, leaving either relatively thick and/or relatively thin LOCOS regions.

Next, in a step 1214, portions of which may have been performed earlier in the method 1200, one or more additional semiconductor features are formed on or in a layer(s) of the semiconductor substrate 102, with like copies of each feature formed into each respective IC on the semiconductor wafer that includes the semiconductor substrate 102. The step 1214 of forming the one or more additional semiconductor features may include almost any process used to form any feature. For example, the step 1214 might include patterning one or more photoresist features on or in connection with the semiconductor substrate 102, including in connection with various layers and levels. Additionally, the step 1214 might include forming one or more interconnect features. The step 1214 also may include other process steps, or a collection of different process steps, so that eventually the items shown in FIG. 11 are formed for each IC on the semiconductor wafer that includes the semiconductor substrate 102.

Next, in a step 1216, the semiconductor wafer including the semiconductor substrate 102 may be coupled to test equipment and tested, after which each IC is cut (diced) from the semiconductor wafer. Thereafter, some or all of the ICs (e.g., those passing testing) are packaged. Packaging typically places a casing around (or encapsulating) the IC and further provides an external interface, typically a number of conductive pins, fixed relative to pads on the die, and conductors such as wire bonds, lands, or balls, are formed between the IC pads and the packaging pins. Thereafter, any packaged IC with an acceptable test result is ready for sale and shipping to a customer.

From the above, one skilled in the art should appreciate that example embodiments are provided for IC semiconductor fabrication, for example with respect to an IC that includes a device, such as a relatively higher voltage transistor, that includes a relatively thick LOCOS structure. Such embodiments provide various benefits, some of which are described above and including still others. For example, embodiments may implement a transistor with relatively smooth boundaries/improved LER along the lateral edges of the LOCOS, thereby providing a basis of improved CD alignment and dimensionality for the device. These benefits may be realized for more complex structures, of for multiple devices on the same substrate (and IC), thereby realizing scaled improvement across the device. Still additional modifications are possible in the described embodiments, and other embodiments are possible, within the scope of the following claims.

What is claimed is:

1. A method of forming an integrated circuit, comprising:
forming a first oxygen diffusion barrier layer in a fixed position relative to a semiconductor substrate;
forming an aperture through the first oxygen diffusion barrier layer and to expose a portion of the semiconductor substrate in an area of the aperture;
forming a first LOCOS region by oxidizing the portion of the semiconductor substrate in an area of the aperture;
forming a second oxygen diffusion barrier layer along the first LOCOS region and along at least a sidewall portion of the first oxygen diffusion barrier layer in the area of the aperture;
depositing a polysilicon layer, at a temperature of 570° C. or less, over the second oxygen diffusion barrier layer;
etching the polysilicon layer and the second oxygen diffusion barrier layer to form a spacer in the area of the aperture; and
forming a second LOCOS region in the area of the aperture and aligned to the spacer.

2. The method of claim 1 and further including, after the etching step and prior to the step of forming a second LOCOS region, removing a polysilicon layer portion of the spacer.

3. The method of claim 1 and further including, after the step of forming a second LOCOS region, removing the spacer.

4. The method of claim 1 wherein the first oxygen diffusion barrier layer includes silicon nitride.

5. The method of claim 1 wherein the second oxygen diffusion barrier layer includes silicon nitride.

6. The method of claim 1 wherein each of the first oxygen diffusion barrier layer and the second oxygen diffusion barrier layer includes silicon nitride.

7. The method of claim 1 wherein the polysilicon layer includes amorphous polysilicon.

8. The method of claim 1 and further including forming a source region and a drain region proximate the second LOCOS region.

9. The method of claim 8 and further including forming a gate conductor adjacent at least a portion of the second LOCOS region.

10. The method of claim 1 and further including forming a gate conductor adjacent at least a portion of the second LOCOS region.

11. The method of claim 10 and further including forming a gate oxide layer adjacent the second LOCOS region, wherein the gate oxide layer is thinner than the second LOCOS region, and wherein the step of forming a gate conductor further includes forming the gate conductor adjacent at least a portion of the gate oxide layer.

12. The method of claim 1 wherein the first oxygen diffusion barrier layer is thicker than the second oxygen diffusion barrier layer.

13. The method of claim 1 and further including forming a capacitor plate adjacent at least a portion of the second LOCOS region.

14. A method of forming an integrated circuit, comprising:
forming a first oxygen diffusion barrier layer in a fixed position relative to a semiconductor substrate;
exposing a portion of the semiconductor substrate through the first oxygen diffusion barrier layer;
oxidizing the portion of the semiconductor substrate and then forming a second oxygen diffusion barrier layer in an area along the oxidized portion of the semiconductor substrate and along at least a sidewall portion of the first oxygen diffusion barrier layer;
depositing an amorphous polysilicon layer over the second oxygen diffusion barrier layer;
etching the polysilicon layer and the second oxygen diffusion barrier layer to form a spacer; and
forming a LOCOS region aligned to the spacer.

15. The method of claim 14 wherein the depositing an amorphous polysilicon includes depositing an amorphous polysilicon at a temperature of 570° C. or less.

16. The method of claim 14 and further including forming a transistor gate conductor adjacent at least a portion of the LOCOS region.

17. The method of claim 14 and further including forming a capacitor plate adjacent at least a portion of the LOCOS region.

18. A method of forming an integrated circuit, comprising:
forming a first oxide region along a portion of a semiconductor substrate;
forming at least one spacer proximate an edge of the oxide region, the spacer including an oxide layer and an amorphous polysilicon layer; and
forming a second oxide region along the first oxide region and aligned to the oxide layer of the spacer.

19. The method of claim 18 wherein the step of forming the at least one spacer includes depositing the amorphous polysilicon layer at a temperature of 570° C. or less.

20. The method of claim 18 and further including forming at least one of a transistor gate conductor or a capacitor plate adjacent the second oxide region.
